(19) United States
(12) Patent Application Publication
(10) Pub. No.: US 2026/0090127 A1
(43) Pub. Date: Mar. 26, 2026

(54) SEMICONDUCTOR PACKAGE

(71) Applicant: SAMSUNG ELECTRONICS CO., LTD., Suwon-si (KR)

(72) Inventors: SHLE-GE LEE, Suwon-si (KR); YUN SEOK CHOI, Suwon-si (KR); SUNWOO HAN, Suwon-si (KR); SANG-UK KIM, Suwon-si (KR)

(21) Appl. No.: 19/090,082

(22) Filed: Mar. 25, 2025

(30) Foreign Application Priority Data
Sep. 23, 2024 (KR) 10-2024-0128487

(51) Int. Cl. H10F 39/00

(52) U.S. Cl. CPC H10F 39/811; H10F 39/804; H10F 39/8053; H10F 39/8057; H10F 39/8063

(57) ABSTRACT

A semiconductor package may include a package substrate including top and bottom surfaces, the top surface including first and second surfaces, the first surface being located at a level higher than the second surface, an image sensor chip on the first surface of the package substrate, a transparent substrate on the image sensor chip, a dam structure on an edge portion of the image sensor chip and between the image sensor chip and the transparent substrate, and a mold layer on the second surface of the package substrate and enclosing the dam structure. The image sensor chip may include a semiconductor substrate including a pixel array region and a pad region extending therearound and a conductive pad on the pad region. The conductive pad may be electrically connected to a connection pad on the second surface of the package substrate.

### CROSS-REFERENCE TO RELATED APPLICATIONS

This U.S. non-provisional patent application claims priority under 35 U.S. C. § 119 to Korean Patent Application No. 10-2024-0128487, filed on Sep. 23, 2024, in the Korean Intellectual Property Office, the disclosure of which is incorporated herein by reference in its entirety.

### BACKGROUND OF THE INVENTION

The present disclosure relates to semiconductor packages, and in particular, to semiconductor packages including an image sensor chip.

An image sensor (e.g., a charge-coupled device (CCD) sensor or a complementary metal-oxide-semiconductor (CMOS) image sensor) is utilized in various electronic products, such as mobile phones, digital cameras, optical mice, security cameras, biometric devices. Due to an increasing demand for small and multifunctional electronic products, a semiconductor package including an image sensor should be prepared to have improved technical properties (e.g., small size, high density, low power consumption, multifunction, high signal-processing speed, high reliability, low cost, and clear image quality). Various researches are being conducted to meet this demand.

### SUMMARY OF THE INVENTION

An embodiment of the inventive concept provides an image sensor chip with improved reliability and a semiconductor package including the same.

According to an embodiment of the inventive concept, a semiconductor package may include a package substrate including a top surface and an opposite bottom surface, the top surface including a first surface and a second surface, wherein the first surface is at a level higher than the second surface, an image sensor chip on the first surface of the package substrate, a transparent substrate on the image sensor chip, a dam structure on an edge portion of the image sensor chip and between the image sensor chip and the transparent substrate, and a mold layer on the second surface of the package substrate and enclosing the dam structure. The image sensor chip may include a semiconductor substrate including a pixel array region and a pad region extending around a periphery of the pixel array region, the pixel array region including a light-receiving region and a light-blocking region between the light-receiving region and the pad region, and a conductive pad on the pad region. The conductive pad of the image sensor chip may be electrically connected to a connection pad, wherein the connection pad is on the second surface of the package substrate.

According to an embodiment of the inventive concept, a semiconductor package may include a package substrate including a top surface and an opposite bottom surface, the top surface including a first surface and a second surface, wherein the first surface is at a level higher than the second surface, an image sensor chip on the first surface of the package substrate, a transparent substrate on the image sensor chip, a dam structure on an edge portion of the image sensor chip and between the image sensor chip and the transparent substrate, and a mold layer on the second surface of the package substrate and enclosing the dam structure. The image sensor chip may include a semiconductor substrate including a pixel array region and a pad region extending around a periphery of the pixel array region, wherein the pixel array region may include a light-receiving region and a light-blocking region between the light-receiving region and the pad region. The mold layer may include a first region on a side surface of the semiconductor substrate, wherein the first region extends to the top surface of the package substrate, and a second region on a side surface of the dam structure, wherein the second region extends to a side surface of the transparent substrate. A ratio between a length of the second region in a first direction and a length of the first region in the first direction may range from 0.68:1 to 1.7:1, and the first direction may be perpendicular to the top surface of the package substrate.

According to an embodiment of the inventive concept, a semiconductor package may include a package substrate including a top surface and an opposite bottom surface, the top surface including a first surface and a second surface, wherein the first surface is at a level higher than the second surface, an image sensor chip on the first surface of the package substrate, a transparent substrate on the image sensor chip, a dam structure on an edge portion of the image sensor chip and between the image sensor chip and the transparent substrate, and a mold layer on the second surface of the package substrate and enclosing the dam structure. The image sensor chip may include a semiconductor substrate including a pixel array region and a pad region extending around a periphery of the pixel array region, the pixel array region including a light-receiving region and a light-blocking region between the light-receiving region and the pad region, color filters on the light-receiving region of the semiconductor substrate, a light-blocking pattern on the light-blocking region of the semiconductor substrate, micro lenses on the color filters, a passivation layer on surfaces of the micro lenses and a top surface of the light-blocking pattern, and a conductive pad on the pad region. The mold layer may include a first region on a side surface of the semiconductor substrate, wherein the first region extends to the top surface of the package substrate, and a second region on a side surface of the dam structure, wherein the second region extends to a side surface of the transparent substrate. The conductive pad of the image sensor chip may be electrically connected to a connection pad on the second surface of the package substrate.

### BRIEF DESCRIPTION OF THE DRAWINGS

FIG. 1 is a plan view illustrating a semiconductor package according to an embodiment of the inventive concept.

FIG. 2 is a sectional view taken along a line I-I′ of FIG. 1.

FIG. 3 is an enlarged sectional view illustrating a portion ‘M’ of FIG. 2.

FIG. 4 is an enlarged sectional view illustrating a portion ‘N’ of FIG. 2.

FIG. 5 is a sectional view illustrating an image sensor according to an embodiment of the inventive concept.

FIGS. 6 to 12 are sectional views illustrating a method of fabricating a semiconductor package according to an embodiment of the inventive concept and corresponding to the line I-I′ of FIG. 1.

FIG. 13 is an enlarged sectional view illustrating a portion ‘O’ of FIG. 12.

FIG. 14 is a sectional view taken along the line I-I′ of FIG. 1 to illustrate a semiconductor package according to example embodiments of the inventive concept.

FIG. 15 is an enlarged sectional view illustrating a portion ‘P’ of FIG. 14.

### DETAILED DESCRIPTION

Example embodiments of the inventive concepts will now be described more fully with reference to the accompanying drawings, in which example embodiments are shown.

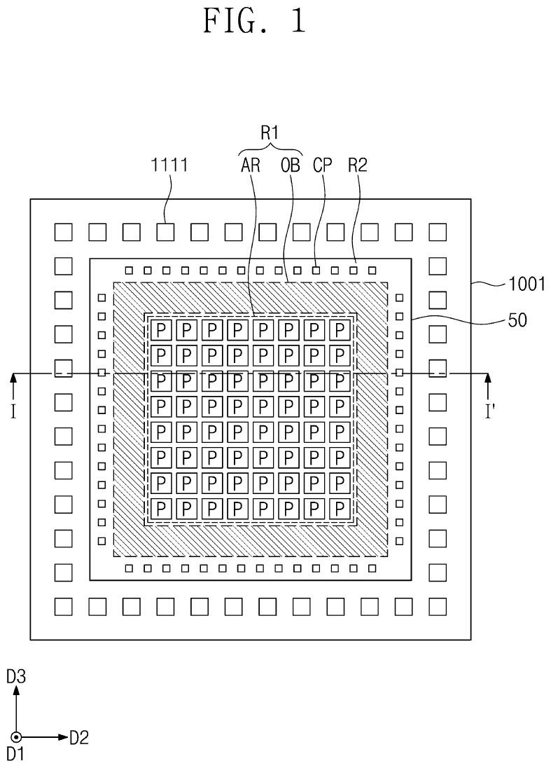

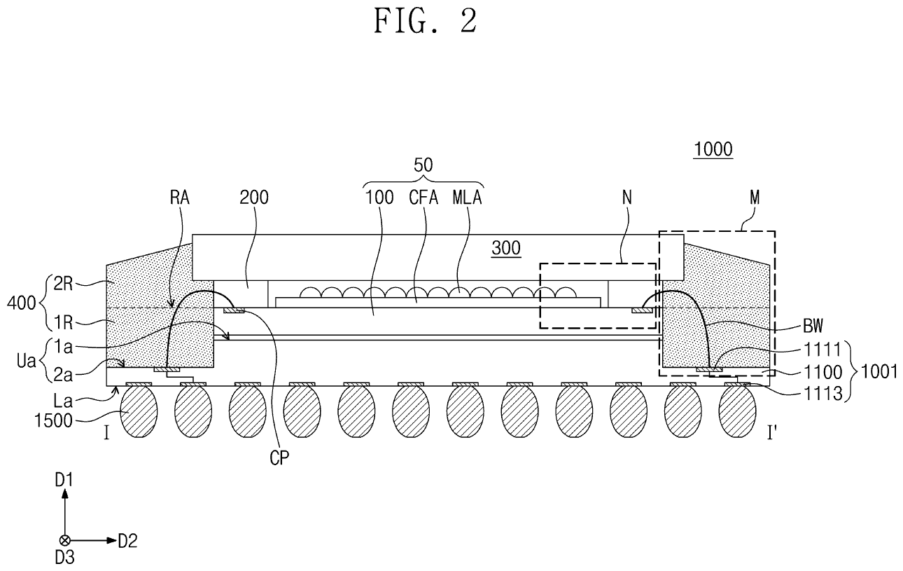

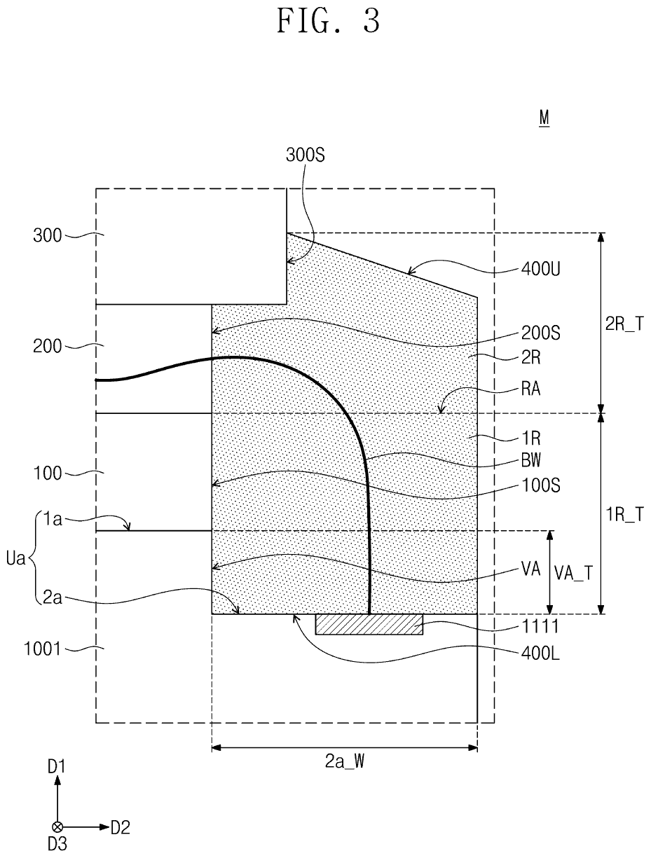

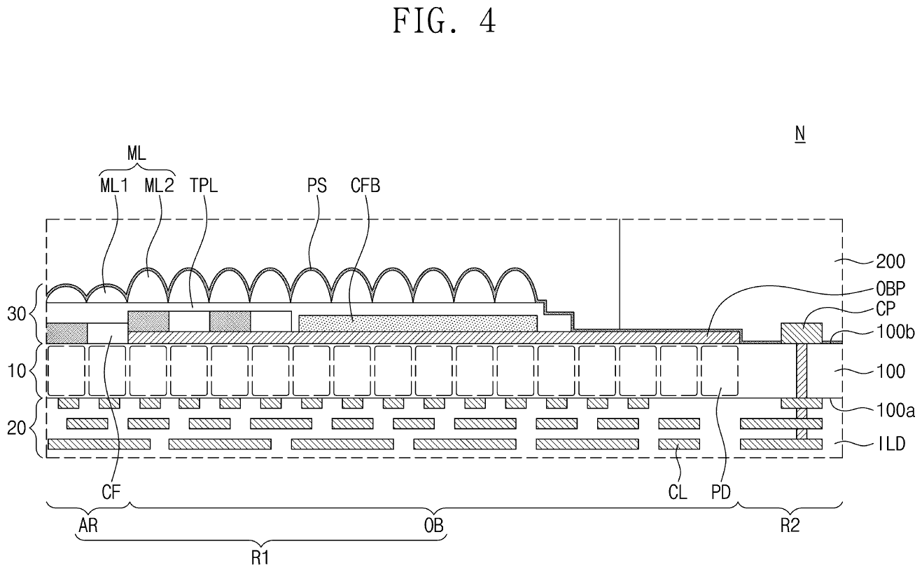

FIG. 1 is a plan view illustrating a semiconductor package according to an embodiment of the inventive concept. FIG. 2 is a sectional view taken along a line I-I′ of FIG. 1. FIG. 3 is an enlarged sectional view illustrating a portion ‘M’ of FIG. 2. FIG. 4 is an enlarged sectional view illustrating a portion ‘N’ of FIG. 2.

Referring to FIGS. 1 and 2, a semiconductor package 1000 may include a package substrate 1001, an image sensor chip 50, a dam structure 200, a transparent substrate 300, and a mold layer 400.

The package substrate 1001 may include a top surface Ua and a bottom surface La, which are opposite to each other. The top surface Ua may include a first surface 1a and a second surface 2a, and the first surface 1a may be located at a level higher than the second surface 2a, as illustrated in FIG. 2. The second surface 2a may be provided in an edge portion of the package substrate 1001. The first surface 1a may be provided in a center portion of the package substrate 1001. The first and second surfaces 1a and 2a may be provided to form a stepwise structure in a vertical direction (e.g., a first direction D1). The second surface 2a may be offset from the first surface 1a in a second direction D2.

Referring to FIGS. 2 and 3, the top surface Ua of the package substrate 1001 may include a vertical plane VA, which is extended in the first direction D1 between the first and second surfaces 1a and 2a. The vertical plane is the side surface of the package substrate 1001 that extends between the first and second surfaces 1a, 2a. In an embodiment, a length VA_T of the vertical plane VT in the first direction D1 may range from 125 μm to 130 μm. A length (i.e., a width 2a_W) in the second direction D2 of the second surface 2a may range from 350 μm to 500 μm.

In the present specification, the first direction D1 may be perpendicular to the top surface Ua of the package substrate 1001. The second direction D2 may be parallel to the top surface Ua of the package substrate 1001 and may be perpendicular to the first direction D1. A third direction D3 may be parallel to the top surface Ua of the package substrate 1001 and may not be parallel to the second direction D2.

In an embodiment, the package substrate 1001 may be a printed circuit board (PCB). The package substrate 1001 may include a base substrate 1100, a connection pad 1111 disposed on a top surface of the base substrate 1100, and a coupling pad 1113 disposed on a bottom surface of the base substrate 1100. The base substrate 1100 may include internal interconnection lines and may be provided to have a single-or multi-layered structure.

The connection pad 1111 may be electrically connected to the coupling pad 1113 through internal interconnection lines. The connection pad 1111 may be electrically connected to the image sensor chip 50 through a bonding wire BW made of a metal material.

The connection pad 1111 may be disposed on the second surface 2a. In an embodiment, a plurality of connection pads 1111 may be provided. The connection pads 1111 may be provided in an edge portion of the base substrate 1100. The connection pads 1111 may be arranged around the image sensor chip 50 mounted on the package substrate 1001 (i.e., the connection pads 1111 are positioned around the periphery of the image sensor chip 50 as illustrated in FIG. 1).

FIG. 1 illustrates an example, in which the connection pads 1111 are arranged to form a single column enclosing the image sensor chip 50, but the inventive concept is not limited to this example. In an embodiment, the connection pads 1111 may be arranged to form two columns enclosing the image sensor chip 50. In an embodiment, the connection pads 1111 may be disposed at both sides of the image sensor chip 50. Connection terminals 1500 (e.g., solder balls or solder bumps) may be attached to the coupling pads 1113.

The image sensor chip 50 may be disposed on the first surface 1a of the package substrate 1001. The image sensor chip 50 may be attached to a top surface of the package substrate 1001 by an adhesive layer or a bonding tape.

Referring to FIGS. 1, 2, and 4, the image sensor chip 50 may include a semiconductor substrate 100, a color filter layer CFA, and a micro lens layer MLA. The semiconductor substrate 100 may include photoelectric conversion devices. In an embodiment, the photoelectric conversion devices may be a photodiode, a phototransistor, a photogate, a pinned photodiode (PPD), and combinations thereof.

The color filter layer CFA may be disposed on the semiconductor substrate 100. The color filter layer CFA may include color filters corresponding to unit pixels P, respectively. The color filters may include blue, red, and green color filters. In an embodiment, the color filters may include magenta, cyan, and yellow color filters. In an embodiment, at least one of the color filters may include a white color filter or an infrared filter.

The micro lens layer MLA may be disposed on the color filter layer CFA. The micro lens layer MLA may include a plurality of micro lenses, which are used to concentrate light incident from the outside. The micro lenses may have an upward convex shape and may have a specific curvature radius. The micro lenses may be configured to change a path of light to be incident into the image sensor chip 50, and this may make it possible to condense the incident light. The micro lenses may be two-dimensionally arranged in the second and third directions D2 and D3, which are not parallel to each other, and may be disposed to face the unit pixels P, respectively. In an embodiment, at least one of the micro lenses may be disposed on at least two photoelectric conversion devices.

The image sensor chip 50 may include a pixel array region R1 and a pad region R2 enclosing the pixel array region R1 (i.e., the pad region R2 extends around the periphery of the pixel array region R1). The pixel array region R1 may include the unit pixels P, which are two-dimensionally arranged in the second and third directions D2 and D3 that are not parallel to each other. Each of the unit pixels P may include a photoelectric conversion device and readout devices. An electrical signal, which is generated by the incident light, may be output from each of the unit pixels P of the pixel array region R1.

The pixel array region R1 may include a light-receiving region AR and a light-blocking region OB. The light-blocking region OB may be provided between the light-receiving region AR and the pad region R2. The light-blocking region OB may enclose the light-receiving region AR, when viewed in a plan view (i.e., the light-blocking region OB extends around the periphery of the light-receiving region AR, when viewed in a plan view). That is, the light-blocking region OB may be disposed around the light-receiving region AR in four different directions (e.g., up, down, left, and rights directions), when viewed in a plan view.

Reference pixels, to which light is not incident, may be provided in the light-blocking region OB, and in this case, by comparing a charge amount, which is obtained from the unit pixels of the light-receiving region AR, with a reference amount of charges generated in the reference pixels, it may be possible to calculate a magnitude of an electrical signal generated by the unit pixel P.

A plurality of conductive pads CP, which are used to input or output control signals and photoelectric signals, may be disposed in the pad region R2. The pad region R2 may be provided to enclose the pixel array region R1, when viewed in a plan view (i.e., the pad region R2 extends around the pixel array region R1, when viewed in plan view), and in this case, the image sensor may be easily connected to an external device. The conductive pads CP may be used to input and output electrical signals, which are generated in the unit pixels P, to and from the external device. The conductive pads CP may be electrically connected to the package substrate 1001 through the bonding wire BW. The conductive pads CP may be electrically connected to the connection pads 1111 through the bonding wire BW.

The dam structure 200 may be disposed between the image sensor chip 50 and the transparent substrate 300. The dam structure 200 may be disposed on an edge portion of the image sensor chip 50 to cover the conductive pads CP. The dam structure 200 may have a closed loop shape.

The dam structure 200 may be provided to fasten the transparent substrate 300 and may separate the image sensor chip 50 and the transparent substrate 300 from each other. A space may be between the transparent substrate 300 and the image sensor chip 50 by the dam structure 200. The dam structure 200 may seal the space between the transparent substrate 300 and the image sensor chip 50, and thus, it may be possible to prevent external moisture or contaminant from entering the empty space. The micro lens layer MLA may not be overlapped with the dam structure 200 vertically (or in a plan view).

The dam structure 200 may include an insulating material. In an embodiment, the dam structure 200 may include at least one selected from the group consisting of epoxy resin, polyimide, and resist. The dam structure 200 may include a dry film resist (DFR) or an insulating material.

The transparent substrate 300 may be spaced apart from the image sensor chip 50 by the dam structure 200. The transparent substrate 300 may be formed of transparent glass, transparent resin, or transparent ceramics. The transparent substrate 300 may have a width larger than the image sensor chip 50, and a thickness of the transparent substrate 300 may be larger than a thickness of the image sensor chip 50.

The mold layer 400 may cover the second surface 2a of the package substrate 1001. The mold layer 400 may be in contact with the vertical plane VA (i.e., with the side surface of the package substrate 1001 that extends from the first surface 1a to the second surface 2a). The mold layer 400 may be provided to seal the image sensor chip 50, the bonding wire BW, the dam structure 200, and the transparent substrate 300. The mold layer 400 may be extended from the second surface 2a of the package substrate 1001 to cover the image sensor chip 50, the dam structure 200, and the side surface 300S of the transparent substrate 300. The mold layer 400 may have a closed loop shape, when viewed in a plan view.

The mold layer 400 may include a first region 1R and a second region 2R. The second region 2R may be disposed on the first region 1R. In detail, the reference plane RA, which is extended from a boundary between the semiconductor substrate 100 and the dam structure 200 in a horizontal direction (e.g., the second direction), may be defined. The first region 1R may be defined as a region below the reference plane RA (e.g., adjacent to the package substrate 1001), and the second region 2R may be defined as a region on the reference plane RA (e.g., adjacent to the transparent substrate 300).

The first region 1R may cover the semiconductor substrate 100 and may be extended to the top surface Ua of the package substrate 1001. The first region 1R may cover the top surface Ua (e.g., the second surface 2a) of the package substrate 1001. The first region 1R may be in contact with the vertical plane VA between the first and second surfaces 1a and 2a (i.e., the side surface of the package substrate 1001 that extends from the first surface 1a to the second surface 2a) and may be in contact with the second surface 2a. The first region 1R may cover a side surface 100S of the semiconductor substrate 100. The first region 1R may include the bottommost surface 400L of the mold layer 400.

The second region 2R may cover a side surface 200S of the dam structure 200 and may be extended to the side surface 300S of the transparent substrate 300. The second region 2R may be in contact with the side surface 200S of the dam structure 200 and may be in contact with at least a portion of the side surface 300S of the transparent substrate 300. The second region 2R may include the topmost surface 400U of the mold layer 400.

A ratio between a volume of the second region 2R and a volume of the first region 1R may range from 0.68:1 to 1.7:1.

In an embodiment, a ratio between a length 2R_T of the second region 2R in the first direction D1 and a length 1R_T of the first region 1R in the first direction D1 may range from 0.68:1 to 1.7:1. The length 2R_T of the second region 2R in the first direction D1 may range from 425 μm to 525 μm. The length 1R_T of the first region 1R in the first direction D1 may range from 325 μm to 625 μm.

The mold layer 400, in conjunction with the dam structure 200, may prevent the image sensor chip 50 from being contaminated by external contamination material(s). In addition, the mold layer 400 may protect the semiconductor package 1000 from an external impact.

The mold layer 400 may have an inclined top surface 400U, and the inclined top surface of the mold layer 400 may be lower than a top surface of the transparent substrate 300. The mold layer 400 may include an epoxy resin composition and may be formed of, for example, an epoxy molding compound (EMC) material.

According to an embodiment of the inventive concept, the mold layer 400 may be disposed to cover the second surface 2a, which is located at a level lower than the first surface 1a. Thus, a volume of the mold layer (e.g., the second region 2R of the mold layer 400) enclosing the dam structure 200 may be reduced. Owing to the reduction of the volume of the second region 2R, it may be possible to reduce an external force exerted on the dam structure (e.g., through the expansion or shrinkage caused by heat generation or moisture absorption during operating the semiconductor package).

Referring to FIGS. 1 and 4, the image sensor chip 50 may include a conversion layer 10, a readout circuit layer 20, and an optically-transparent layer 30.

The conversion layer 10 may be disposed between the readout circuit layer 20 and the optically-transparent layer 30, when viewed in a vertical section (FIG. 4). The conversion layer 10 may include the semiconductor substrate 100 and the photoelectric conversion parts PD, which are provided in the semiconductor substrate 100.

The semiconductor substrate 100 may be doped with first impurities to have a first conductivity type. The first impurities may be, for example, boron. The first conductivity type may be, for example, a p-type.

The semiconductor substrate 100 may include a third surface 100a and a fourth surface 100b, which are opposite to each other. Light may be incident into the semiconductor substrate 100 through the fourth surface 100b. The semiconductor substrate 100 may be a single crystalline wafer or an epitaxial layer, which includes silicon and/or germanium, or a silicon-on-insulator (SOI) substrate.

The photoelectric conversion part PD may be doped with second impurities to have a second conductivity type different from the first conductivity type. The second impurity may be, for example, phosphorus or arsenic. The second conductivity type may be, for example, an n-type.

In the pad region R2, the conductive pads CP may be provided in a region adjacent to an edge portion of the semiconductor substrate 100. The conductive pads CP may be used to input and output electrical signals, which are produced in the unit pixels, to and from an external device.

The readout circuit layer 20 may be disposed on the third surface 100a of the semiconductor substrate 100. The readout circuit layer 20 may include the readout circuits (e.g., MOS transistors) connected to the conversion layer 10. An electrical signal, which is converted by the conversion layer 10, may be processed by the readout circuit layer 20. The readout circuit layer 20 may include pixel transistors, such as a reset transistor, a source follower transistor, and a selection transistor.

In detail, the readout circuit layer 20 may include MOS transistors, which are disposed on a bottom surface of the semiconductor substrate 100, connection lines CL, which are connected to the MOS transistors, and interlayer insulating layers ILD, which are interposed between the connection lines CL. The connection lines CL may be provided to have a multi-layered structure, and the connection lines CL, which are located at different levels, may be connected to each other through contact plugs.

The optically-transparent layer 30 may be disposed on the fourth surface 100b of the semiconductor substrate 100. The optically-transparent layer 30 may include color filters CF, a light-blocking pattern OBP, an upper planarization layer TPL, micro lenses ML, and a passivation layer PS.

In the light-receiving region AR and the light-blocking region OB, the color filters CF may be disposed on the fourth surface 100b of the semiconductor substrate 100. The color filters CF may be disposed to correspond to the photoelectric conversion parts PD, respectively. Here, the color filters CF, which are disposed on the light-blocking region OB, may be provided to correspond to only some of the photoelectric conversion parts PD. The color filters CF may include red, green, or blue color filters or may include magenta, cyan, or yellow color filters, depending on the type of the unit pixel.

In the light-blocking region OB, the light-blocking pattern OBP may be disposed on the fourth surface 100b of the semiconductor substrate 100. The light-blocking pattern OBP may be extended in the second direction D2.

The color filters CF, which are disposed on the light-blocking region OB, may be provided on the light-blocking pattern OBP. Due to the light-blocking pattern OBP, the top surfaces of the color filters CF disposed on the light-blocking region OB may be located at a level that is higher than the top surfaces of the color filters CF disposed on the light-receiving region AR.

The light-blocking pattern OBP may be configured to prevent light from being incident into the semiconductor substrate 100. The light-blocking pattern OBP may be formed of or include at least one of metallic materials and/or metal nitride materials. For example, the light-blocking pattern OBP may be formed of or include tungsten, titanium, and/or titanium nitride.

In the light-blocking region OB, a bulk filtering layer CFB may be provided on the light-blocking pattern OBP. The bulk filtering layer CFB may be provided to block light whose wavelength is different from the color filters CF. In an embodiment, the bulk filtering layer CFB may be configured to block the infrared light. The bulk filtering layer CFB may include a blue color filter, but the inventive concept is not limited to this example.

In the light-receiving region AR and the light-blocking region OB, the upper planarization layer TPL may be disposed on the color filters CF and the light-blocking pattern OBP. In detail, the upper planarization layer TPL may cover the color filters CF and the bulk filtering layer CFB. A side surface of the upper planarization layer TPL may have a stepwise structure, near the pad region R2.

The upper planarization layer TPL may include a transparent insulating material. The upper planarization layer TPL may include an organic material (e.g., a polymer). For example, the upper planarization layer TPL may be formed of or include glass, epoxy resin, silicon resin, polyurethane, other possible materials, or combinations thereof. Alternatively, the upper planarization layer TPL may be formed of or include silicon oxide or silicon oxynitride.

The micro lenses ML may be disposed on the upper planarization layer TPL. The micro lenses ML may have an upward convex shape and may have a specific curvature radius. The micro lenses ML may include first micro lenses ML1 disposed on the light-receiving region AR and second micro lenses ML2 disposed on the light-blocking region OB. In an embodiment, the second micro lenses ML2 may be dummy micro lenses. A level of a top surface of the second micro lenses ML2 may be higher than a level of a top surface of the first micro lenses ML1.

The passivation layer PS may conformally cover the micro lenses ML. The passivation layer PS may be extended along top surfaces of the micro lenses ML to cover the side surface of the upper planarization layer TPL. At least a portion of the passivation layer PS may be in contact with the dam structure 200. At least a portion of the passivation layer PS may be in contact with a side surface of the dam structure 200. The passivation layer PS may include an inorganic oxide material.

According to an embodiment of the inventive concept, owing to the reduction of the volume of the second region 2R, it may be possible to reduce an external force exerted on the dam structure 200 (e.g., through the expansion or shrinkage caused by the heat generation or moisture absorption during operating the semiconductor package). Due to the reduction of the external force, it may be possible to reduce a stress exerted on the passivation layer PS by the dam structure 200. Due to the reduction of the stress, it may be possible to prevent a crack issue from occurring in the passivation layer PS. The reliability and stability of the semiconductor package 1000 may be improved.

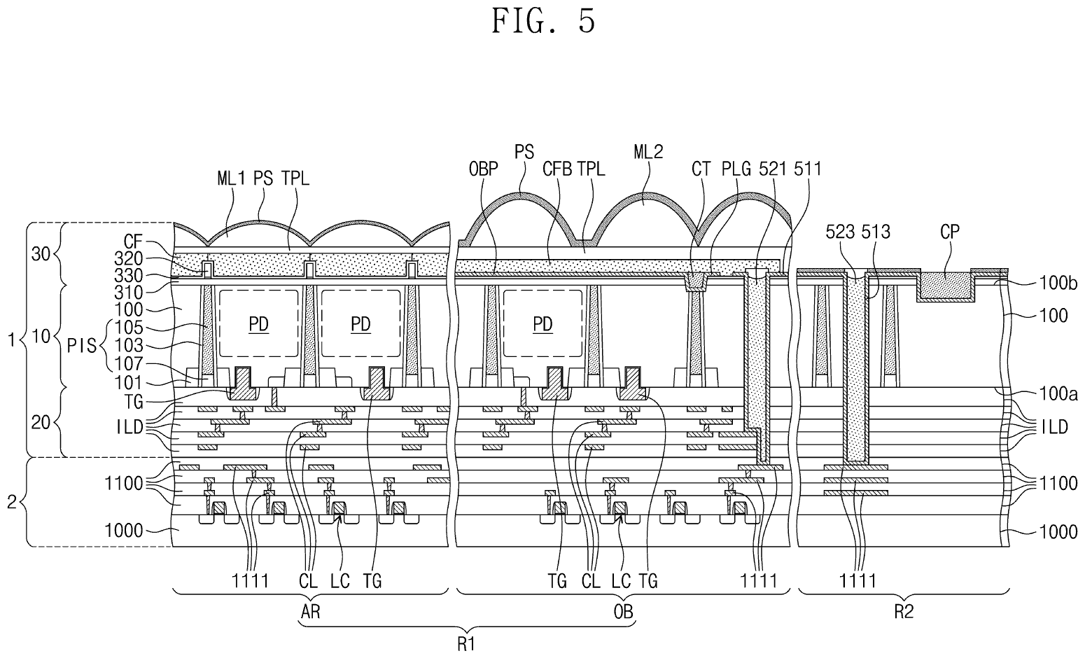

FIG. 5 is a sectional view illustrating an image sensor according to an embodiment of the inventive concept. An element previously described with reference to FIGS. 1 to 4 may be identified by the same reference number without repeating an overlapping description thereof.

Referring to FIG. 5, the image sensor chip 50 may include a sensor unit 1 and a logic unit 2 on the sensor unit 1. As described above, the sensor unit 1 may include a photoelectric conversion layer 10, which is provided between the readout circuit layer 20 and the optically-transparent layer 30 when viewed in a vertical section.

In each of the pixel regions, a device isolation layer 101 may be disposed adjacent to the third surface 100a of the semiconductor substrate 100. The device isolation layer 101 may define an active portion in the semiconductor substrate 100 near the third surface 100a. The device isolation layer 101 may include an insulating material.

Isolation structures PIS may be provided in the semiconductor substrate 100 to separate the photoelectric conversion parts PD from each other. The isolation structure PIS may be vertically extended from the third surface 100a of the semiconductor substrate 100 to the fourth surface 100b. In an embodiment, the isolation structure PIS may be provided to penetrate a portion of the device isolation layer 101.

The isolation structure PIS may include a liner insulating pattern 103, a semiconductor pattern 105, and a gapfill insulating pattern 107. In an embodiment, the semiconductor pattern 105 may be formed of or include at least one of doped polysilicon or metallic materials.

The liner insulating pattern 103 may be provided between the semiconductor pattern 105 and the semiconductor substrate 100. The gapfill insulating pattern 107 may be disposed below the semiconductor pattern 105. The liner insulating pattern 103 and the gapfill insulating pattern 107 may include silicon oxide.

In the light-blocking region OB, the semiconductor pattern 105 may be connected to a bias contact plug PLG. The bias contact plug PLG may be formed of or include at least one of metallic materials and/or metal nitride materials. For example, the bias contact plug PLG may include titanium and/or titanium nitride.

A contact pattern CT may be placed in a contact hole provided with the bias contact plug PLG. The contact pattern CT may include a material different from the bias contact plug PLG. For example, the contact pattern CT may be formed of or include aluminum (Al).

A negative bias may be applied to the semiconductor pattern 105 through the contact pattern CT and the bias contact plug PLG. In the light-blocking region OB, the negative bias may be transmitted to the light-receiving region AR. Since a negative bias is applied to the semiconductor pattern 105 of the isolation structure PIS, it may be possible to reduce a dark current which is produced at a boundary between the isolation structure PIS and the semiconductor substrate 100.

Transfer gate electrodes TG may be disposed on the third surface 100a of the semiconductor substrate 100. The transfer gate electrode TG may include a protruding portion inserted into the semiconductor substrate 100, and a gate insulating layer may be interposed between the transfer gate electrode TG and the semiconductor substrate 100. The gate insulating layer may be formed of or include at least one of silicon oxide, silicon oxynitride, a high-k dielectric material, which have a dielectric constant higher than silicon oxide, or combinations thereof.

A floating diffusion region may be provided in a portion of the semiconductor substrate 100 adjacent to the transfer gate electrode TG. The floating diffusion region may be formed by injecting impurities into the semiconductor substrate 100. In an embodiment, due to the presence of the impurities, the floating diffusion region may be an n-type impurity region.

The interlayer insulating layers ILD may cover the transfer gate electrode TG and pixel transistors, on the third surface 100a of the semiconductor substrate 100.

The optically-transparent layer 30 may be disposed on the fourth surface 100b of the semiconductor substrate 100. In detail, the optically-transparent layer 30 may include a lower planarization insulating layer 310, a grid 320, a protection layer 330, the color filters CF, the light-blocking pattern OBP, the first and second micro lenses ML1 and ML2, and a second protection pattern PS2.

The lower planarization insulating layer 310 may cover the fourth surface 100b of the semiconductor substrate 100. The lower planarization insulating layer 310 may be extended from the light-receiving region AR to the light-blocking region OB and the pad region R2. The lower planarization insulating layer 310 may be formed of a transparent insulating material and may include a plurality of layers. The lower planarization insulating layer 310 may be formed of an insulating material having a refractive index different from the semiconductor substrate 100. The lower planarization insulating layer 310 may be formed of or include at least one of metal oxide materials and/or silicon oxide.

The lower planarization insulating layer 310 may have a single-or multi-layered structure. In an embodiment, the lower planarization insulating layer 310 may be formed of metal oxide or metal fluoride containing at least one metallic element that is selected from the group consisting of hafnium (Hf), zirconium (Zr), aluminum (Al), tantalum (Ta), titanium (Ti), yttrium (Y) and lanthanum (La). For example, the lower planarization insulating layer 310 may include an aluminum oxide layer and/or a hafnium oxide layer.

The grid 320 may be disposed on the lower planarization insulating layer 310. The grid 320 may include a light-blocking pattern and/or a low-refractive pattern. The light-blocking pattern may be formed of or include at least one of metallic materials (e.g., titanium, tantalum, or tungsten). The low-refractive pattern may be formed of a material having a refraction index lower than the light-blocking pattern. The low-refractive pattern may be formed of an organic material and may have a refractive index of about 1.1 to 1.3.

The protection layer 330 may cover the lower planarization insulating layer 310 and the grid 320. The protection layer 330 may be formed of or include at least one of aluminum oxide or silicon oxide. The protection layer 330 may be extended from the light-receiving region AR to the light-blocking region OB and the pad region R2.

The color filters CF may be disposed to correspond to the pixel regions, respectively. The color filters CF may include red, green, or blue color filters or may include magenta, cyan, or yellow color filters, depending on the type of the unit pixel.

In the light-blocking region OB, a first conductive penetration pattern 511 may be provided to penetrate the semiconductor substrate 100 and may be electrically connected to the connection lines CL of the readout circuit layer 20 and an interconnection structure 1111 of the logic unit 2. The first conductive penetration pattern 511 may have a first bottom surface and a second bottom surface, which are located at different levels. A first gapfill pattern 521 may be provided in the first conductive penetration pattern 511. The first gapfill pattern 521 may include a low-refractive material and may exhibit an insulating property.

In the pad region R2, the conductive pads CP may be provided on the fourth surface 100b of the semiconductor substrate 100. The conductive pads CP may be provided in the semiconductor substrate 100 near the fourth surface 100b. In an embodiment, the conductive pads CP may be provided in a pad trench, which is formed in the semiconductor substrate 100 near the fourth surface 100b, on the pad region R2. The conductive pads CP may be formed of or include at least one of metallic materials (e.g., aluminum, copper, tungsten, titanium, tantalum, or alloys thereof). The conductive pads CP may be electrically connected to an external device through bonding wires.

In the pad region R2, a second conductive penetration pattern 513 may be provided to penetrate the semiconductor substrate 100 and may be electrically connected to the interconnection structure 1111 of the logic unit 2. The second conductive penetration pattern 513 may be extended to the fourth surface 100b of the semiconductor substrate 100 and may be electrically connected to the conductive pads CP. A portion of the second conductive penetration pattern 513 may cover bottom and side surfaces of the conductive pads CP. A second gapfill pattern 523 may be provided in the second conductive penetration pattern 513. The second gapfill pattern 523 may include a low-refractive material and may exhibit an insulating property. In the pad region R2, the isolation structures PIS may be provided around the second conductive penetration pattern 513.

The logic unit 2 may be disposed adjacent to the readout circuit layer 20 of the sensor unit 1. The logic unit 2 may include a power circuit, an input/output interface, and an image signal processor. The logic unit 2 may include a logic semiconductor substrate 1000, logic circuits LC integrated on the logic semiconductor substrate 1000, the interconnection structures 1111 connected to the logic circuits, and logic interlayer insulating layers 1100 provided on the logic semiconductor substrate 1000. The uppermost one of the logic interlayer insulating layers 1100 may be bonded to the readout circuit layer 20 of the sensor unit 1. The logic unit 2 may be electrically connected to the sensor unit 1 through the first and second conductive penetration patterns 511 and 513.

In an embodiment, the sensor unit 1 and the logic unit 2 are illustrated to be electrically connected to each other through the first and second conductive penetration patterns 511 and 513, but the inventive concept is not limited to this example. In an embodiment, the first and second conductive penetration patterns shown in FIG. 5 may be omitted, and in this case, the sensor unit 1 and the logic unit 2 may be bonded to each other through contact pads and may be electrically connected to each other.

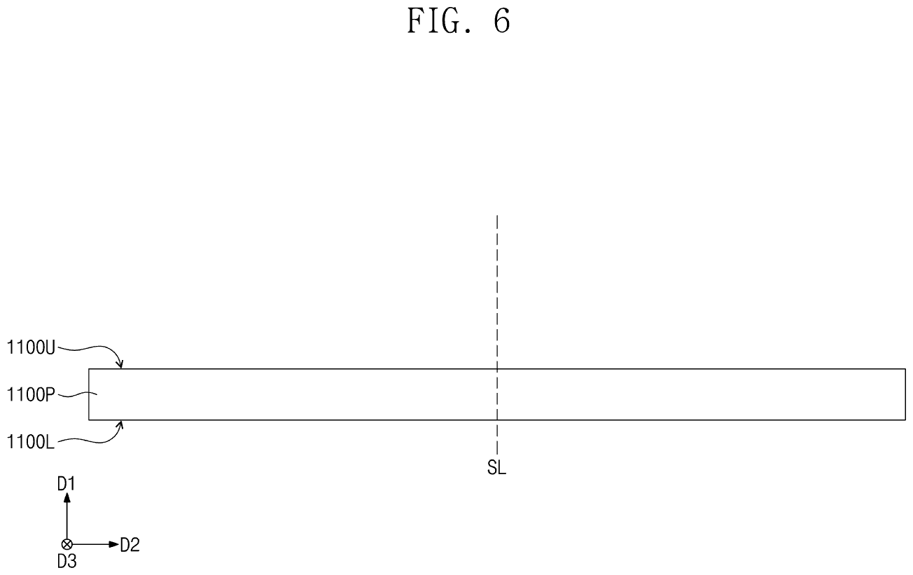

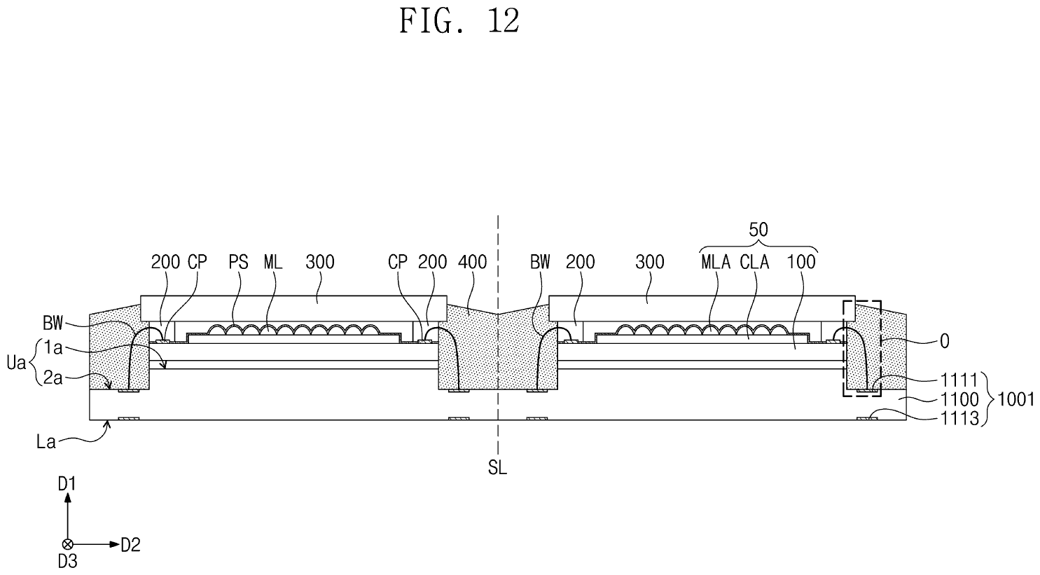

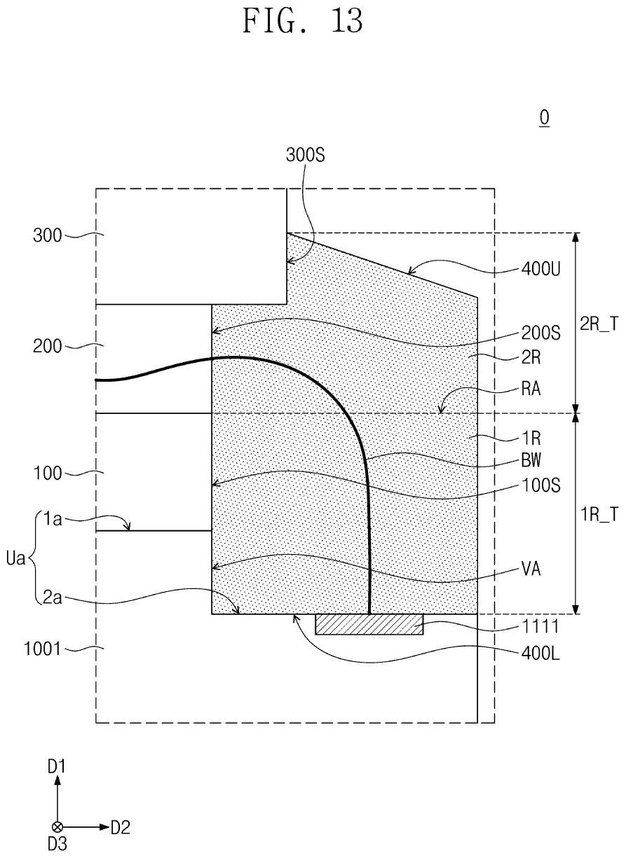

FIGS. 6 to 12 are sectional views illustrating a method of fabricating a semiconductor package according to an embodiment of the inventive concept and corresponding to the line I-I′ of FIG. 1. FIG. 13 is an enlarged sectional view illustrating a portion ‘O’ of FIG. 12. For concise description, an element described with reference to FIGS. 1 to 4 may be identified by the same reference number without repeating an overlapping description thereof.

Referring to FIG. 6, a preliminary substrate 1100P may be provided. The preliminary substrate 1100P may include a top surface 1100U and a bottom surface 1100L, which are opposite to each other.

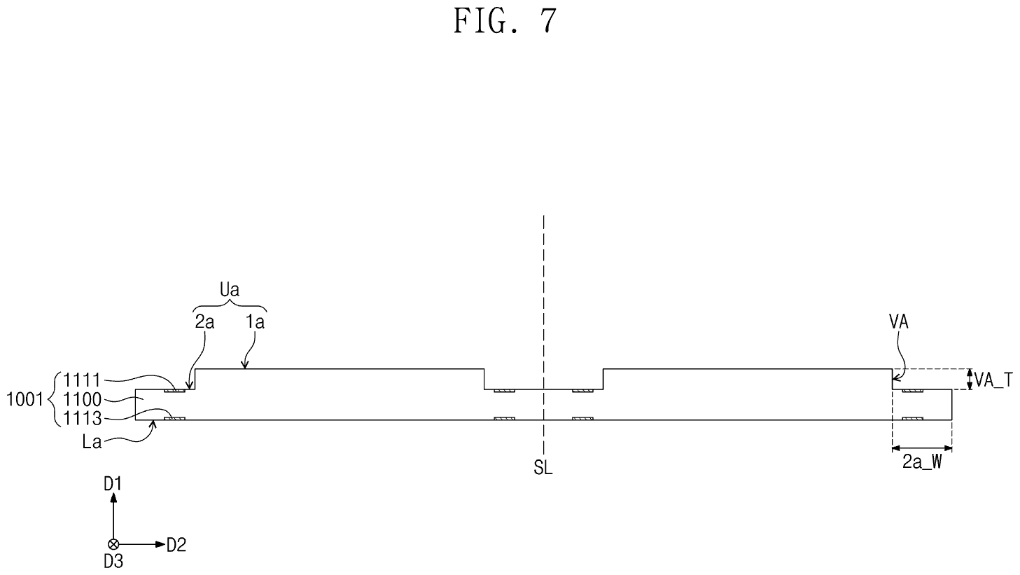

Referring to FIG. 7, the first and second surfaces 1a and 2a may be formed on the top surface 1100U of the preliminary substrate 1100P. The first surface 1a may be located at a level higher than the second surface 2a. The second surface 2a may be located at a level lower than the first surface 1a. The first and second surfaces 1a and 2a may be provided to form a stepwise structure in a vertical direction (e.g., the first direction D1). The second surface 2a may be offset from the first surface 1a in the second direction D2. In an embodiment, a length (i.e., the width 2a_W) of the second surface 2a in the second direction D2 may range from 350 μm to 500 μm.

In an embodiment, the formation of the first and second surfaces 1a and 2a may include forming a mask pattern on the preliminary substrate 1100P and etching the preliminary substrate 1100P using the mask pattern as an etch mask. In an embodiment, a plurality of second surfaces 2a may be formed. The first surface 1a may be interposed between the second surfaces 2a. The base substrate 1100 may be formed through the etching process.

The connection pad 1111 may be formed on the second surface 2a. A top surface of the connection pad 1111 may be exposed to the outside. Although not shown, a solder resist layer may be formed on the top surface 1100U to expose the top surface of the connection pad 1111. The coupling pad 1113 may be formed on the bottom surface 1100L. Although not shown, a solder resist layer may be formed on the bottom surface 1100L to expose a top surface of the coupling pad.

The base substrate 1100, the connection pad 1111, and the coupling pad 1113 may be provided to form the package substrate 1001. The top surface 1100U of the preliminary substrate 1100P may be referred to as the top surface Ua of the package substrate 1001, and the bottom surface 1100L of the preliminary substrate 1100P may be referred to as the bottom surface La of the package substrate 1001.

The top surface Ua of the package substrate 1001 may include the vertical plane VA (i.e., the side surface of the package substrate 1001 that extends from the first surface 1a to the second surface 2a), which is extended in the first direction D1 and is provided between the first and second surfaces 1a and 2a. In an embodiment, the length VA_T of the vertical plane VT in the first direction D1 may range from 120 μm to 130 μm.

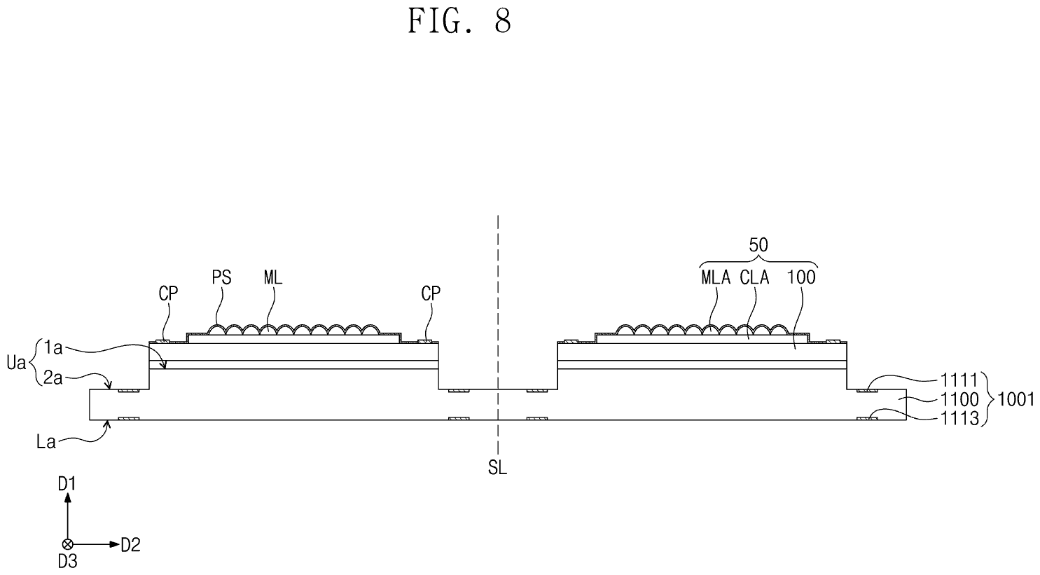

Referring to FIG. 8, the image sensor chip 50 may be attached and fastened to the first surface 1a of the package substrate 1001. As described above, the image sensor chip 50 may include the semiconductor substrate 100, the color filter layer CFA, and the micro lens layer MLA. The color filter layer CFA may include color filters and a light-blocking pattern. The micro lens layer MLA may include the micro lenses ML and the passivation layer PS. The passivation layer PS may cover the top surfaces of the micro lenses ML.

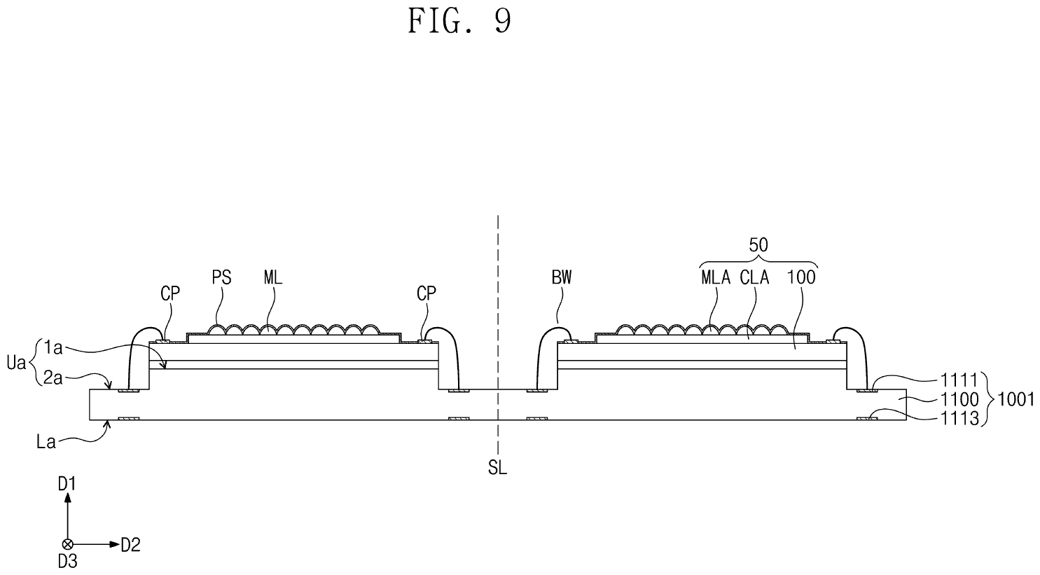

Referring to FIG. 9, a wire bonding process may be performed to connect the conductive pad CP of the image sensor chip 50 to a corresponding one of the connection pads 1111 of the package substrate 1001 through the bonding wire BW. The wire bonding process may be performed using, for example, a capillary. As a result of the wire bonding process, a first end of the bonding wire BW may be connected to the conductive pad CP, and a second end may be connected to the connection pad 1111. The bonding wire BW may be formed of or include at least one of metallic materials (e.g., gold (Au)), but the inventive concept is not limited to this example.

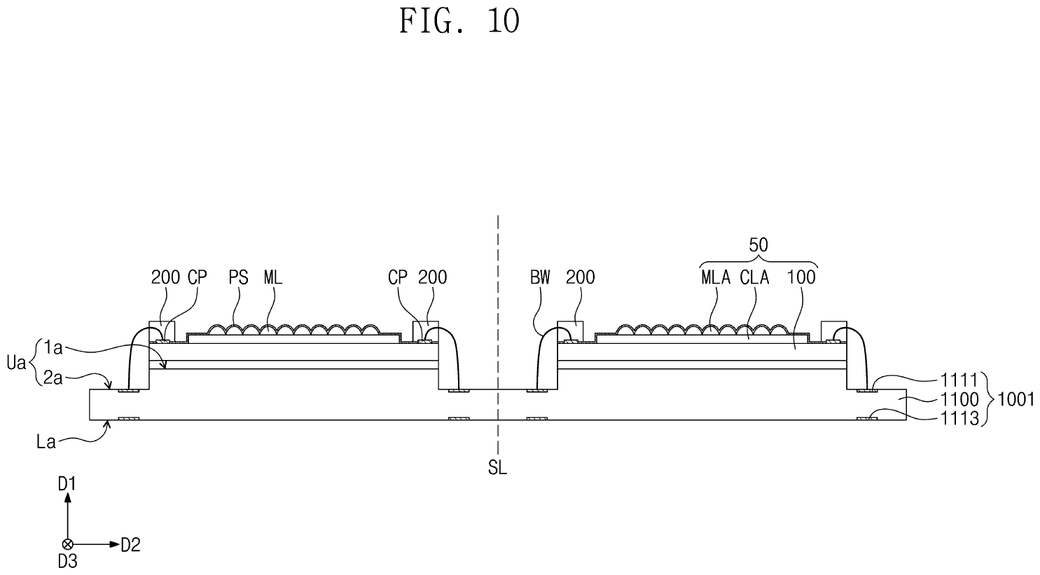

Referring to FIG. 10, the dam structure 200 may be formed on a top surface of the image sensor chip 50. The dam structure 200 may be formed by a dispensing method using a dispenser. In an embodiment, the dam structure 200 may be formed by supplying an adhesive material using a nozzle. The dam structure 200 may be formed of a glue adhesive, and the glue adhesive may include fillers. The dam structure 200 may be provided on the pad region of the image sensor chip 50 and may have a tetragonal closed loop shape enclosing the semiconductor substrate 100. The dam structure 200 may be in contact with at least a portion of the passivation layer PS. The dam structure 200 may cover the conductive pad CP of the image sensor chip 50 and the first end of the bonding wire BW connected thereto.

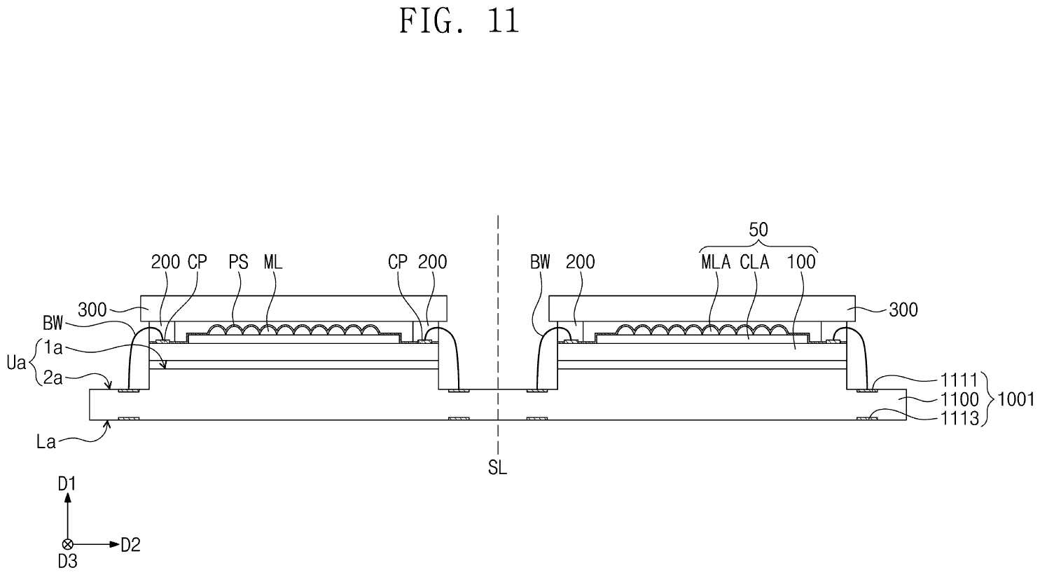

Referring to FIG. 11, the transparent substrate 300 may be attached to the dam structure 200. For example, the transparent substrate 300 may be placed on the dam structure 200, and the transparent substrate 300 may be fastened to the dam structure 200 by applying heat and pressure. Due to the transparent substrate 300, an empty space may be formed between the transparent substrate 300 and the image sensor chip 50.

Referring to FIGS. 12 and 13, the mold layer 400 may be formed on the package substrate 1001. The mold layer 400 may be formed to cover the second surface 2a of the package substrate 1001 and to be in contact with the vertical plane VA (i.e., with the side surface of the package substrate 1001 that extends from the first surface 1a to the second surface 2a).

The mold layer 400 may be provided to seal the image sensor chip 50, the bonding wire BW, the dam structure 200, and the transparent substrate 300. The mold layer 400 may cover the image sensor chip 50 and the side surface 200S of the dam structure 200. Furthermore, the mold layer 400 may partially cover the side surface 300S and the bottom surface of the transparent substrate 300. The mold layer 400 may be formed to expose the top surface of the transparent substrate 300. The mold layer 400 may be provided to cover the connection pad 1111 of the package substrate 1001 and the second end of the bonding wire BW attached thereto.

The mold layer 400 may include the first region 1R and the second region 2R. The second region 2R may be disposed on the first region 1R. In detail, the reference plane RA, which is extended from the boundary between the semiconductor substrate 100 and the dam structure 200 in a horizontal direction (e.g., the second direction), may be defined. The first region 1R may be defined as a region below the reference plane RA (e.g., adjacent to the package substrate 1001), and the second region 2R may be defined as a region on the reference plane RA (e.g., adjacent to the transparent substrate 300).

The first region 1R may cover the semiconductor substrate 100 and may be extended to the top surface Ua of the package substrate 1001. The first region 1R may cover the top surface Ua (e.g., the second surface 2a) of the package substrate 1001. The first region 1R may be in contact with the vertical plane VA between the first and second surfaces 1a and 2a (i.e., the side surface of the package substrate 1001 that extends from the first surface 1a to the second surface 2a) and may be in contact with the second surface 2a. The first region 1R may cover the side surface 100S of the semiconductor substrate 100. The first region 1R may include the bottommost surface 400L of the mold layer 400.

The second region 2R may cover the side surface 200S of the dam structure 200 and may be extended to the side surface 300S of the transparent substrate 300. The second region 2R may be in contact with the side surface 200S of the dam structure 200 and may be in contact with at least a portion of the side surface 300S of the transparent substrate 300. The second region 2R may include the topmost surface 400U of the mold layer 400.

In an embodiment, the ratio between the volume of the second region 2R and the volume of the first region 1R may range from 0.68:1 to 1.7:1.

In an embodiment, a ratio between the length 2R_T of the second region 2R in the first direction D1 and the length 1R_T of the first region 1R in the first direction D1 may range from 0.68:1 to 1.7:1. The length 2R_T of the second region 2R in the first direction D1 may range from 425 μm to 525 μm. The length 1R_T of the first region 1R in the first direction D1 may range from 325 μm to 625 μm.

According to an embodiment of the inventive concept, the mold layer 400 may be disposed to cover the second surface 2a located at a lower level, and in this case, a volume of the mold layer (e.g., the second region 2R of the mold layer) enclosing the dam structure may be reduced.

Owing to the reduction of the volume of the second region 2R, it may be possible to reduce an external force exerted on the dam structure 200 (e.g., through the expansion or shrinkage caused by heat generation or moisture absorption during operating the semiconductor package).

Due to the reduction of the external force, it may be possible to reduce a stress exerted on the passivation layer PS by the dam structure 200. Due to the reduction of the stress, it may be possible to prevent a crack issue from occurring in the passivation layer PS. The reliability and stability of the semiconductor package 1000 may be improved.

Referring back to FIG. 2, the connection terminals 1500 (e.g., solder balls) may be attached to the coupling pads 1113 of the package substrate 1001, after the formation of the mold layer 400. Thereafter, a sawing process may be performed along the sawing line SL (e.g., of FIG. 12) between the image sensor chips 50 to form semiconductor packages that are separated from each other. The sawing process may be performed to cut the mold layer 400 and the package substrate 1001.

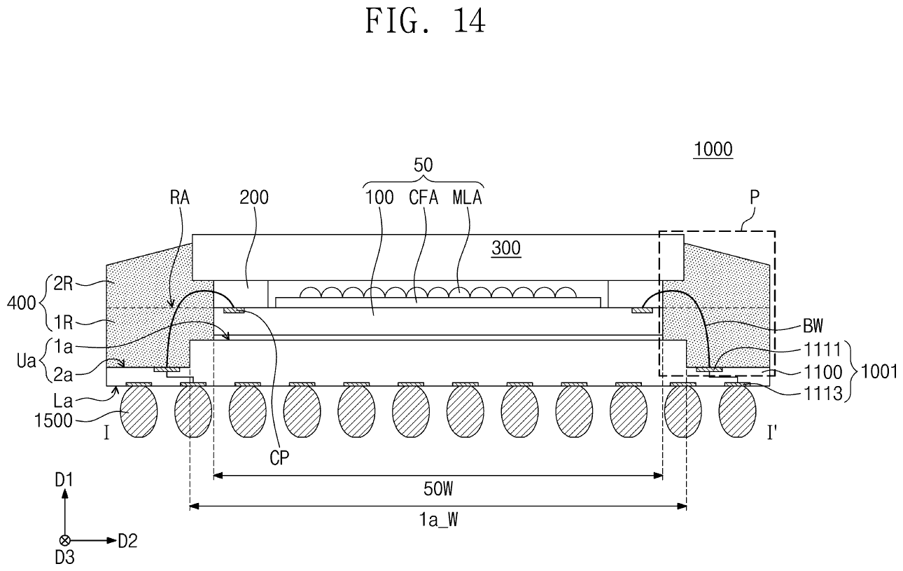

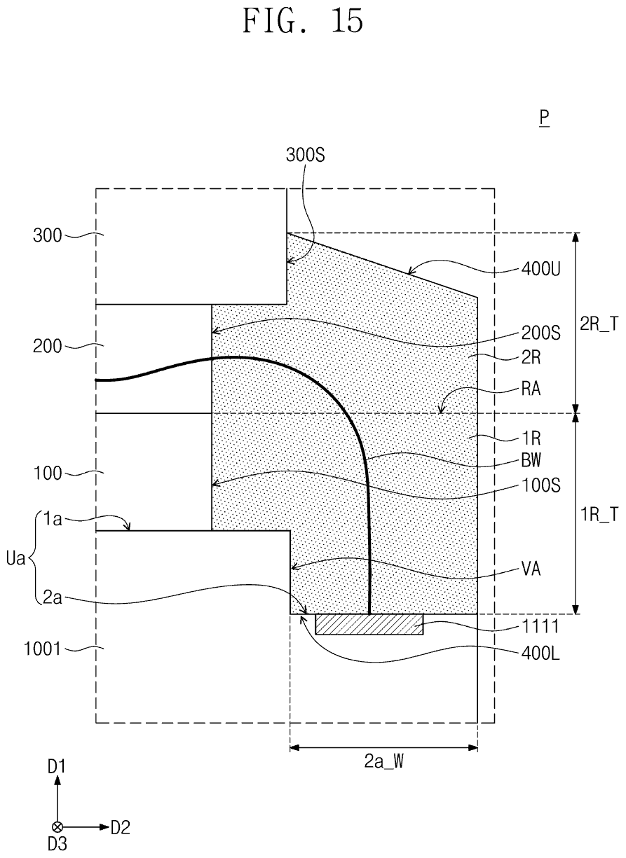

FIG. 14 is a sectional view taken along the line I-I′ of FIG. 1 to illustrate a semiconductor package according to example embodiments of the inventive concept. FIG. 15 is an enlarged sectional view illustrating a portion ‘P’ of FIG. 14. For concise description, an element described with reference to FIGS. 1 to 4 may be identified by the same reference number without repeating an overlapping description thereof.

Referring to FIG. 14, the package substrate 1001 may include the top surface Ua and the bottom surface La, which are opposite to each other. The top surface Ua may include the first surface 1a and the second surface 2a, and the first surface 1a may be located at a level higher than the second surface 2a. The second surface 2a may be provided in an edge portion of the package substrate 1001. The first surface 1a may be provided in the center portion of the package substrate 1001. The first and second surfaces 1a and 2a may be provided to form a stepwise structure in a vertical direction (e.g., the first direction D1). The second surface 2a may be offset from the first surface 1a in the second direction D2.

The image sensor chip 50 may be mounted on the first surface 1a of the package substrate 1001. A length 1a_W of the first surface 1a in the second direction D2 may be larger than a length 50W of the image sensor chip 50 in the second direction D2. A portion of the first surface 1a may be exposed from the image sensor chip 50.

Referring to FIGS. 14 and 15, the mold layer 400 may cover the first and second surfaces 1a and 2a on the package substrate 1001. The mold layer may cover the exposed portion of the first surface 1a. The mold layer 400 may be in contact with the vertical plane VA (i.e., with the side surface of the package substrate 1001 that extends from the first surface 1a to the second surface 2a).

The mold layer 400 may be provided to seal the image sensor chip 50, the bonding wire BW, the dam structure 200, and the transparent substrate 300. The mold layer 400 may be extended from the second surface 2a of the package substrate 1001 to cover the image sensor chip 50, the dam structure 200, and the side surface 300S of the transparent substrate 300. The mold layer 400 may have a closed loop shape, when viewed in a plan view.

The mold layer 400 may include the first region 1R and the second region 2R. The second region 2R may be disposed on the first region 1R. In detail, the reference plane RA, which is extended from the boundary between the semiconductor substrate 100 and the dam structure 200 in a horizontal direction (e.g., the second direction), may be defined. The first region 1R may be defined as a region below the reference plane RA (e.g., adjacent to the package substrate 1001), and the second region 2R may be defined as a region on the reference plane RA (e.g., adjacent to the transparent substrate 300).

The first region 1R may cover the semiconductor substrate 100 and may be extended to the top surface Ua of the package substrate 1001. The first region 1R may cover the top surface Ua of the package substrate 1001 and may cover a portion of the first and second surfaces 1a and 2a. The first region 1R may be in contact with the vertical plane VA (i.e., with the side surface of the package substrate 1001 that extends from the first surface 1a to the second surface 2a) between the first and second surfaces 1a and 2a and may be in contact with a portion of the first and second surfaces 1a and 2a. The first region 1R may cover the side surface 100S of the semiconductor substrate 100. The first region 1R may include the bottommost surface 400L of the mold layer 400.

The second region 2R may cover the side surface of the dam structure 200 and may be extended to the side surface 300S of the transparent substrate 300. The second region 2R may be in contact with the side surface 200S of the dam structure 200 and may be in contact with at least a portion of the side surface 300S of the transparent substrate 300. The second region 2R may include the topmost surface 400U of the mold layer 400.

In an embodiment, a ratio between a volume of the second region 2R and the volume of the first region 1R may range from 0.68:1 to 1.7:1.

In an embodiment, a ratio between the length 2R_T of the second region 2R in the first direction D1 and the length 1R_T of the first region 1R in the first direction D1 may range from 0.68:1 to 1.7:1. The length 2R_T of the second region 2R in the first direction D1 may range from 425 μm to 525 μm. The length 1R_T of the first region 1R in the first direction D1 may range from 325 μm to 625 μm.

According to an embodiment of the inventive concept, the mold layer 400 may be disposed to cover the second surface 2a, which is located at a level lower than the first surface 1a. Thus, a volume of the mold layer (e.g., the second region 2R of the mold layer 400) enclosing the dam structure 200 may be reduced. Owing to the reduction of the volume of the second region 2R, it may be possible to reduce an external force exerted on the dam structure (e.g., through the expansion or shrinkage caused by heat generation or moisture absorption during operating the semiconductor package).

In addition, the length 1a_W of the first surface 1a in the second direction D2 may be larger than the length 50W of the image sensor chip 50 in the second direction D2. The rigidity of the package substrate 1001 may be improved.

Except for the above features, the semiconductor package may be configured to have substantially the same features as one of the semiconductor packages described with reference to FIGS. 1 to 5.

According to an embodiment of the inventive concept, a package substrate may have a first surface and a second surface, which is located at a level lower than the first surface. A mold layer may be disposed to cover the second surface, and in this case, a volume of the mold layer surrounding a dam structure may be reduced. Thus, it may be possible to reduce an external force exerted on the dam structure through the expansion or shrinkage of the mold layer (e.g., caused by heat generation or moisture absorption during operating the semiconductor package). Since the external force is reduced, a stress exerted on a passivation layer by the dam structure may be reduced. This may make it possible to prevent a crack issue from occurring in the passivation layer. Accordingly, a semiconductor package with improved reliability and stability may be provided.

While example embodiments of the inventive concept have been particularly shown and described, it will be understood by one of ordinary skill in the art that variations in form and detail may be made therein without departing from the scope of the attached claims.

What is claimed is:

1. A semiconductor package, comprising:
a package substrate comprising a top surface and an opposite bottom surface, the top surface comprising a first surface and a second surface, wherein the first surface is at a level higher than the second surface;
an image sensor chip on the first surface of the package substrate;
a transparent substrate on the image sensor chip;
a dam structure on an edge portion of the image sensor chip and between the image sensor chip and the transparent substrate; and
a mold layer on the second surface of the package substrate and enclosing the dam structure,
wherein the image sensor chip comprises:
a semiconductor substrate comprising a pixel array region and a pad region extending around a periphery of the pixel array region, the pixel array region comprising a light-receiving region and a light-blocking region between the light-receiving region and the pad region; and
a conductive pad on the pad region,
wherein the conductive pad of the image sensor chip is electrically connected to a connection pad, wherein the connection pad is on the second surface of the package substrate.

2. The semiconductor package of claim 1, wherein the image sensor chip further comprises:
color filters on the light-receiving region of the semiconductor substrate;
a light-blocking pattern on the light-blocking region of the semiconductor substrate;
micro lenses on the color filters; and
a passivation layer on surfaces of the micro lenses and a top surface of the light-blocking pattern,
wherein at least a portion of the passivation layer is in contact with the dam structure.

3. The semiconductor package of claim 1, wherein the mold layer comprises:
a first region on a side surface of the semiconductor substrate, wherein the first region extends to the top surface of the package substrate; and
a second region on a side surface of the dam structure, wherein the second region extends to a side surface of the transparent substrate,
wherein a ratio between a length of the second region in a first direction and a length of the first region in the first direction ranges from 0.68:1 to 1.7:1, and
wherein the first direction is perpendicular to the top surface of the package substrate.

4. The semiconductor package of claim 3, wherein a ratio between a volume of the first region and a volume of the second region ranges from 1:0.68 to 1:1.7.

5. The semiconductor package of claim 3, wherein the package substrate comprises a side surface which extends in the first direction between the first and second surfaces,
wherein the first region is in contact with the side surface of the package substrate, and
wherein the first direction is perpendicular to the top surface of the package substrate.

6. The semiconductor package of claim 3, wherein a length of the second region in the first direction ranges from 425 μm to 525 μm, and
wherein a length of the first region in the first direction ranges from 325 μm to 625 μm.

7. The semiconductor package of claim 1, wherein a length of the first surface in a second direction is larger than a length of the image sensor chip in the second direction, and
wherein the second direction is parallel to the top surface of the package substrate.

8. The semiconductor package of claim 1, wherein the package substrate comprises a side surface which extends in a first direction between the first and second surfaces,
wherein a length of the side surface of the package substrate in the first direction ranges from 120 μm to 130 μm, and
wherein the first direction is perpendicular to the top surface of the package substrate.

9. The semiconductor package of claim 1, wherein a length of the second surface in a second direction ranges from 350 μm to 500 μm, and
the second direction is parallel to the top surface of the package substrate.

10. The semiconductor package of claim 2, wherein the mold layer comprises an epoxy resin composition,
wherein the passivation layer comprises an inorganic oxide material, and
wherein the dam structure comprises epoxy resin and/or polyimide.

11. A semiconductor package, comprising:
a package substrate comprising a top surface and an opposite bottom surface, the top surface comprising a first surface and a second surface, wherein the first surface is at a level higher than the second surface;
an image sensor chip on the first surface of the package substrate;
a transparent substrate on the image sensor chip;
a dam structure on an edge portion of the image sensor chip and between the image sensor chip and the transparent substrate; and
a mold layer on the second surface of the package substrate and enclosing the dam structure,
wherein the image sensor chip comprises a semiconductor substrate comprising a pixel array region and a pad region extending around a periphery of the pixel array region,
wherein the pixel array region comprises a light-receiving region and a light-blocking region between the light-receiving region and the pad region,
wherein the mold layer comprises:
a first region on a side surface of the semiconductor substrate, wherein the first region extends to the top surface of the package substrate; and
a second region on a side surface of the dam structure, wherein the second region extends to a side surface of the transparent substrate,
wherein a ratio between a length of the second region in a first direction and a length of the first region in the first direction ranges from 0.68:1 to 1.7:1, and
wherein the first direction is perpendicular to the top surface of the package substrate.

12. The semiconductor package of claim 11, further comprising:
a conductive pad on the pad region of the image sensor chip; and
a connection pad on the second surface of the package substrate,
wherein the conductive pad and the connection pad are electrically connected to each other.

13. The semiconductor package of claim 11, wherein the image sensor chip further comprises:
color filters on the light-receiving region of the semiconductor substrate;
a light-blocking pattern on the light-blocking region of the semiconductor substrate;
micro lenses on the color filters; and
a passivation layer on surfaces of the micro lenses and a top surface of the light-blocking pattern,
wherein at least a portion of the passivation layer is in contact with the dam structure.

14. The semiconductor package of claim 13, wherein the mold layer comprises an epoxy resin composition,
wherein the passivation layer comprises an inorganic oxide, and
wherein the dam structure comprises epoxy resin and/or polyimide.

15. The semiconductor package of claim 11, wherein a ratio between a volume of the first region and a volume of the second region ranges from 1:0.68 to 1:1.7.

16. A semiconductor package, comprising:
a package substrate comprising a top surface and an opposite bottom surface, wherein the top surface comprises a first surface and a second surface, wherein the first surface is at a level higher than the second surface;
an image sensor chip on the first surface of the package substrate;
a transparent substrate on the image sensor chip;
a dam structure on an edge portion of the image sensor chip and between the image sensor chip and the transparent substrate; and
a mold layer on the second surface of the package substrate and enclosing the dam structure,
wherein the image sensor chip comprises:
a semiconductor substrate comprising a pixel array region and a pad region extending around a periphery of the pixel array region, the pixel array region comprising a light-receiving region and a light-blocking region between the light-receiving region and the pad region;
color filters on the light-receiving region of the semiconductor substrate;
a light-blocking pattern on the light-blocking region of the semiconductor substrate;
micro lenses on the color filters;
a passivation layer on surfaces of the micro lenses and a top surface of the light-blocking pattern; and
a conductive pad on the pad region,
wherein the mold layer comprises:
a first region on a side surface of the semiconductor substrate, wherein the first region extends to the top surface of the package substrate; and
a second region on a side surface of the dam structure, wherein the second region extends to a side surface of the transparent substrate,
wherein the conductive pad of the image sensor chip is electrically connected to a connection pad on the second surface of the package substrate.

17. The semiconductor package of claim 16, wherein at least a portion of the passivation layer is in contact with the dam structure.

18. The semiconductor package of claim 16, wherein a ratio between a length of the second region in a first direction and a length of the first region in the first direction ranges from 0.68:1 to 1.7:1, and
wherein the first direction is perpendicular to the top surface of the package substrate.

19. The semiconductor package of claim 16, wherein a ratio between a volume of the first region and a volume of the second region ranges from 1:0.68 to 1:1.7.

20. The semiconductor package of claim 16, wherein the package substrate comprises a side surface which extends in a first direction between the first and second surfaces,
wherein the first direction is perpendicular to the top surface of the package substrate, and
wherein the mold layer is in contact with the vertical plane.
